(19) United States
(12) Patent Application Publication
(10) Pub. No.: US 2011/0227760 A1
(43) Pub. Date: Sep. 22, 2011

(54) INPUT PERIPHERAL

(76) Inventors: Paul Kry, Montreal (CA); Adeline Pihuit, Grenoble (FR); Marie-Paule Cani, Meylan (FR)

(21) Appl. No.: 13/003,250

(22) PCT Filed: Jul. 2, 2009
(86) PCT No.: PCT/FR09/00821

§ 371 Date: May 17, 2011

(30) Foreign Application Priority Data
Jul. 8, 2008 (FR) 0803877

(51) Int. Cl. H03K 17/94

(52) U.S. Cl. 341/20

(57) ABSTRACT

An input peripheral comprises a grip linked to a base. The grip is mobile in a chosen number of degrees of freedom with respect to the base. The peripheral also includes sensors designed to deliver a signal characteristic of a displacement of the grip with respect to the base. The peripheral furthermore comprises at least one force sensor linked to the grip in a manner that is substantially tied in terms of displacement to the periphery of the latter, in such a way that the grip and the force sensor may be invoked simultaneously by a user's hand.

### CROSS-REFERENCE TO RELATED APPLICATIONS

This application is a National Phase of International Application No. PCT/FR2009/000821, filed on Jul. 2, 2009, which claims priority to French Application No. 0803877 filed on Jul. 8, 2008, which applications are hereby incorporated by reference in there entirety.

### TECHNICAL FIELD

The disclosure relates to an input peripheral for controlling a computer object.

### BACKGROUND

Since the invention of the mouse, many attempts have been made for extending the control possibilities by a human hand. These attempts were all aimed at making the control more ergonomic and/or closer to purely manual control.

Devices or peripherals have thus been developed, which allow multi-dimensional control, with up to 12 degrees of freedom or more, and optionally combined with active or passive haptic devices.

However, such known devices are not very ergonomic, generally mobilize both hands of the user, and cannot practically be assimilated to gestures of a user.

Other devices have been developed which are generally configured as gloves which reproduce the position of the hand of the user, whether this occurs by means of optical, magnetic, acoustic or mechanical sensors.

These glove-like devices are particularly bulky and not very ergonomic, notably because the holding of a position by the user is very tiring.

Finally, there exist peripherals with 6 degrees of freedom which may be used with a single hand, such as Space Navigator (registered trademark of 3DConnection Holding in Switzerland). However, these devices only allow navigation, and do not give the possibility of taking into account the movement of the fingers of a hand for example.

As this appears, none of the solutions proposed hitherto now provides a satisfactory solution.

### SUMMARY

An input peripheral is disclosed herein, the peripheral including a grip connected to a base, mobile in a selected number of degrees of freedom with respect to the base. This peripheral also includes sensors laid out for delivering a characteristic signal of a displacement of the grip with respect to the base.

This peripheral further includes at least one force sensor linked to said grip in a manner that is substantially tied in terms of displacement to the periphery of the latter, in such a way that said grip and said force sensor may be invoked simultaneously by a user's hand.

Such a peripheral is extremely interesting since it is efficient and ergonomic, while allowing the taking into account of an action of the user by means of his/her fingers, which improves reproduction of the movement of a hand.

### BRIEF DESCRIPTION OF THE DRAWINGS

Other features and advantages of the invention will become better apparent upon the reading the description which follows, drawn from examples given as an illustration and not as a limitation, drawn from drawings wherein:

FIG. 1 illustrates a schematic perspective view of a peripheral according to an embodiment of the disclosure, linked to a computer;

FIG. 2 illustrates a front face of the peripheral of FIG. 1; and

FIG. 3 illustrates a top view of the peripheral of FIG. 1.

The drawings and description hereafter essentially contain elements of a sure nature. They may therefore not only be used for better understanding the present disclosure, but also for contributing to its definition, if need be.

### DETAILED DESCRIPTION

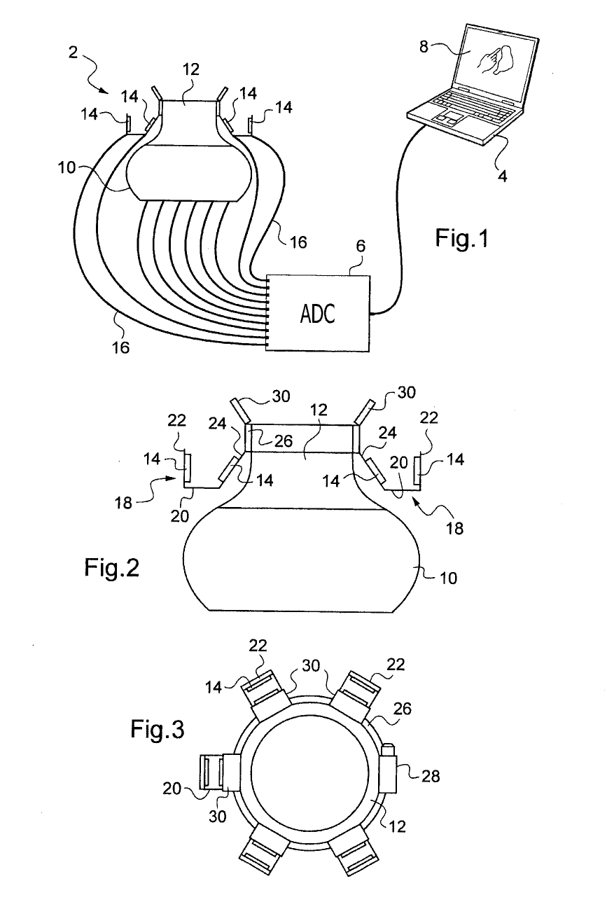

FIG. 1 illustrates a schematic perspective view of an input peripheral 2 according to and embodiment of the disclosure, linked to a computer 4. The peripheral 2 is also connected to an analogue/digital converter 6 called an ADC hereafter.

With the peripheral 2 in the example described here it is possible to control the interaction of a virtual hand with virtual clay on a screen 8 of the computer 4. For this, the peripheral 2 has a base 10 and a grip 12 to which are linked force sensors 14 positioned at the periphery of the grip 12.

The peripheral 2 will be further described with FIGS. 2 to 4. The base 10 is directly linked to the computer 8 and each force sensor 14 is linked to the ADC 6 through wires 16. Finally, the ADC 6 is also linked to the computer 4 in order to transmit force data from the force sensors 14.

The computer 4 includes a software package for acquiring the data sent by the peripheral 2. An example of such a software package is a hardware driver which will convert the data of the peripheral 2 into input for a model reproducing the movement of a hand.

Thus, the data sent by the base 10 may be interpreted as describing the forces applied to the palm of a hand, and the data sent by the sensors 14 may be interpreted as describing a force applied at the tip of a finger connected to this palm in a constrained direction.

Next, a model for the articulation of a virtual hand allows conversion of these data in order to reproduce the movement of the hand on the screen 8. An example of such a model is given in the article “Interaction Capture and Synthesis” ACM Transactions on Graphics (2006), 25.-3, 872-880 by Kry, P and Pai, D. K, the contents of which are incorporated by reference in its entirety.

A suitable software package, for example a virtual modeling software package, may then reproduce the interaction of this hand with clay, in order to allow the making of virtual preforms in an extremely close way to what an artist would do during “physical” modeling.

The peripheral 2 will now be further described by means of FIGS. 2 and 3.

As this may be seen in FIG. 2, the base 10 and the grip 12 of the described embodiment correspond to the elements making up a Space Navigator (registered trademark) which is commercially available.

The grip 12 is mounted on the base 10 with 6 degrees of freedom (3 degrees of freedom of rotation and 3 degrees of freedom of displacement), and is used for capturing the forces applied by the palm of the hand. The base 10 houses sensors (not shown) and which emit a characteristic signal of the movement of the grip 12 with respect to the base 10.

In an upper portion, the grip 12 receives at its periphery, housings or arms 18. In the example described here, the grip 12 receives five arms 18, each corresponding to a finger of a hand.

As this is better seen in FIG. 2, an arm 18 comprises a substantially U-shaped frame 20. The U-frame 20 has two branches numbered as 22 and 24 respectively, the branch 22 being the most distant from the grip 12, and the branch 24 being the closest to the grip 12.

The branch 22 extends substantially vertically with respect to the surface on which the peripheral 2 rests. The branch 24 also extends substantially vertically, and is slightly tilted towards the grip 12, to which it is linked by tightening to a belt 26.

As this is better seen in FIG. 3 the belt 26 surrounds the periphery of the grip 12, and the tightening of the arms 18 is ensured by a nut system 28.

Further, in order to ensure comfort of use, each arm 18 comprises a rigid petal 30 covered with flexible material on which the finger of a user will rest during the operation of the peripheral 2.

In the example described here, the material is a foam. Other materials may be used for covering the petals 30, such as latex. The petals 30 may also be directly made in plastic or in a thin metal sheet.

In addition to comfort of use, the petals 30 ensure the receiving of the finger so that the sensors 14 may be actuated with the distal phalange of each finger while the other phalanges may be used with the palm in order to handle the grip 12. Thus, the user may easily control the grip 12 independently on the one hand, and the sensors 14 on the other hand.

Optionally, the arm 18 also comprises a petal positioned at the end of the branch 22 and which has a function similar to that of the petal 30.

The arm 22 and the arm 24 each receive a force sensor 14. The force sensor 14 allows measurement of pressure of a finger of the user in a direction associated with each of both of these sensors. It will be noted that the outputs of the wires for connection to the ADC 6 are voluntarily omitted in FIGS. 3 and 4.

In the example described here, the peripheral 2 is used so as to reproduce as closely as possible on the computer 4 the movements of a hand handling it. As this has been mentioned above, the computer 4 stores for this purpose a hand deformation model, which models the latter like a palm to which are attached jointed fingers.

The signal delivered by the base 10 characterizes the movement of the palm. The sensors 14 deliver signals characterizing a force applied in a selected direction at the end of the relevant finger.

For example, the sensor 14 positioned on the branch 22 is associated with a force tending to close the finger towards the palm, and the sensor 14 positioned on the branch 24 is associated with a force in a direction opposite to the latter.

Next, the model in the computer 4 uses the data from the ADC 6 and from the base 10 for calculating an equivalent position of the hand on the screen 8.

In other embodiments, the forces may be provided along other directions and be applied elsewhere than at the tip of the finger. Further other models exist for characterizing the deformation of a hand. Moreover, although each arm includes two branches, it would be possible to add other ones, for measuring pressures of the finger in other directions.

Thus, thanks to the peripheral 2, a user may control a first element in six dimensions, and use his/her fingers independently for controlling them virtually. This is particularly useful for virtual sculpture.

Moreover, as this solution is based on the measurement of exerted forces, when the user removes his/her fingers, the hand remains in the last assumed position. This is extremely advantageous as compared with the solutions based on gloves, in which the sole holding of a position is very trying.

Finally, although the application described here is particularly oriented towards virtual sculpture, there exists many other possible applications.

Firstly, the invention is not limited to the sole field of virtual sculpture, but naturally extends to any type of virtual environment in which a virtual hand may be used, or in which more than 6 degrees of freedom are useful.

Further, the invention may also be used for handling real objects. Thus, instead of a hand, the peripheral 2 may for example be used for controlling a crane, the base and the grip being used for handling the jib, and the arms allowing control of other elements.

The foregoing description has the purpose of describing a particular exemplary embodiment of the invention. It cannot be considered as limiting or describing the latter in a limiting way, and notably covers the whole of the combinations of the features with each other of the described alternatives.

What is claimed:

1. An input peripheral, comprising:
a grip linked to a base, said grip being mobile in a selected number of degrees of freedom with respect to the base, as well as
sensors laid out so as to deliver a characteristic signal of a displacement of the grip with respect to the base, and
at least one force sensor linked to said grip in a manner that is substantially tied in terms of displacement to the periphery of said grip, in such a way that said grip and said force sensor may be invoked simultaneously by a user's hand.

2. The peripheral according to claim 1, further comprising a housing configured for receiving a finger of a hand laid on said grip and wherein said force sensor is received in said housing.

3. The peripheral according to claim 2 wherein the housing is an arm connected to a belt tightened around the periphery of the grip.

4. The peripheral according to claim 3, wherein the arm is substantially U-shaped and includes two branches, one of which is linked to said belt.

5. The peripheral according to claim 4, wherein one of said branches includes a petal configured for receiving the tip of a finger of a user's hand at said belt.

6. The peripheral according to claim 1, wherein several force sensors are positioned at a periphery of said grip.

7. The peripheral according to claim 6, wherein at least some of the force sensors are associated pairwise.

8. The peripheral according to claim 7, wherein each of the force sensors associated pairwise are substantially positioned facing each other at the periphery of the grip.
